(19) United States
(12) Patent Application Publication
(10) Pub. No.: US 2015/0228617 A1
(43) Pub. Date: Aug. 13, 2015

(54) SEMICONDUCTOR DEVICE AND METHOD OF MANUFACTURING THE SAME

(71) Applicant: Electronics and Telecommunications Research Institute, Daejeon (KR)

(72) Inventors: Haksun LEE, Daejeon (KR); KWANG-SEONG CHOI, Daejeon (KR); Yong Sung EOM, Daejeon (KR); Hyun-cheol BAE, Daejeon (KR)

(21) Appl. No.: 14/338,050

(22) Filed: Jul. 22, 2014

(30) Foreign Application Priority Data
Feb. 10, 2014 (KR) 10-2014-0015017

(51) Int. Cl. H01L 23/00

(52) U.S. Cl. CPC H01L 24/83; H01L 24/32; H01L 2224/32501; H01L 2224/83948; H01L 2224/32505; H01L 2224/83851

(57) ABSTRACT

Provided is a semiconductor device and a method of manufacturing the same. In the method of manufacturing a semiconductor device, a substrate is prepared which is transparent and has a plurality of first electrodes thereon, and a semiconductor chip having a plurality of second electrodes thereon is disposed on the substrate to allow the first and second electrodes to respectively face each other. A polymer layer including solder particles and an oxidizing agent is formed between the substrate and the semiconductor chip, and the solder particles is locally fused between the first and second electrodes by using a laser beam and a fused solder layer is formed which electrically connects between the first and second electrodes.

### CROSS-REFERENCE TO RELATED APPLICATIONS

This U.S. non-provisional patent application claims priority under 35 U.S.C. §119 of Korean Patent Application No. 10-2014-0015017, filed on Feb. 10, 2014, the entire contents of which are hereby incorporated by reference.

### BACKGROUND OF THE INVENTION

The present invention disclosed herein relates to a semiconductor device and a method of manufacturing the same, and more particularly, to a display package and a method of manufacturing the same

An anisotropic conductive film (ACF) is used as a bonding material in a technology such as a tape carrier package (TCP), a chip-on-flex (COF), or a chip-on-glass (COG), which is an existing package bonding technology for display commercialized and frequently used.

The case where an upper chip and a substrate are electrically connected is exemplarily described. Each of the upper chip and the substrate includes metal pads or electrodes for electrical connection, and a material filling between the electrodes is the ACF. The ACF contains a polymer including conductive particles and has a structure that, when heat and pressure are applied, the polymer is cured and the conductive particles contact to and bond the upper and lower electrodes. In a thermo-compression bonding method, high heat and pressure are applied for instantaneous bonding of the ACF, and at this time, the heat may be transferred to a driving IC and affect device characteristics. In addition, when the substrate includes an organic material, modification and stress occur in the substrate.

The bonding using the ACF has a limitation in causing relatively high contact resistance. This bonding method, not depending on compounds between metals but depending on mechanical contacts between the conductive particles and both electrodes, causes higher contact resistance than a typical bonding method using solders. In addition, since it is difficult to control behaviors of dispersed conductive particles when the heat and pressure are applied, imbalance in the number of particles sandwiched between the electrodes and even an electrical short circuit between adjacent electrodes are caused.

Since the number of particles sandwiched between electrodes is limited, such a bonding method using the ACF results in high contact resistance. When a distribution of particles is increased for improving this, a short circuit may be caused and it is difficult to stably maintain low contact resistance.

Furthermore, the bonding method using the ACF also has a limitation in reliability. When an external stress is applied to the ACF bonding structure and a flexible substrate is deformed, mechanically contacted conductive particles may be easily separated from both electrodes. In addition, when applied to a real product, it is highly possible to absorb moistures according to use environment. The polymer absorbing moistures may expand in volume and adhesion of the conductive particles may be lowered. In addition, even in a heat cycle test, reliability becomes weak due to volume expansion.

### SUMMARY OF THE INVENTION

The present invention provides a semiconductor device having bonding stability, excellent electrical characteristics, and reliability in external stress, moisture absorption or a heat cycle.

The present invention also provides a method of manufacturing the semiconductor device.

Technical issues obtainable from the present invention are non-limited the above mentioned technical issues. And, other unmentioned technical issues can be clearly understood from the following description by those having ordinary skill in the technical field to which the present invention pertains.

Embodiments of the present invention provide methods of manufacturing a semiconductor device, including: preparing a substrate transparent and having a plurality of first electrodes thereon; disposing a semiconductor chip having a plurality of second electrodes thereon on the substrate to allow the first and second electrodes to respectively face each other; forming a polymer layer including solder particles and an oxidizing agent between the substrate and the semiconductor chip; and locally fusing the solder particles between the first and second electrodes by using a laser beam and forming a fused solder layer electrically connecting between the first and second electrodes.

In some embodiments, the locally fusing of the solder particles may includes: locally irradiating the substrate having the first electrode formed thereon with a laser beam; transferring local heat to around the first and second electrodes by using the laser beam; activating the oxidizing agent in a polymer by the heat transferred to around the first and second electrodes and removing oxide films on surfaces of the first and second electrodes; and fusing solder particles adjacent to the first and second electrodes from which the oxide films are removed, and wetting and bonding to the first and second electrodes.

In other embodiments, the laser beams may be sequentially irradiated on each of the plurality of first electrodes.

In still other embodiments, a plurality of laser beams may be irradiated on the plurality of first electrodes at a time.

In even other embodiments, the method may further include: after the forming of the fused solder layer, removing a remained polymer layer; and filling an underfill between the substrate and the semiconductor chip.

In yet other embodiments, while the solder particles between the first and second electrodes are locally fused by using a laser beam and the fused solder layer which electrically connects the first and second electrodes is formed, external pressure may not be applied.

In further embodiments, the method may further include curing the polymer layer by using a curing agent after the forming of the fused solder layer, wherein the polymer layer further includes the curing agent.

In other embodiments of the present invention, semiconductor devices include: a substrate having a plurality of first electrodes; a semiconductor chip having a plurality of second electrodes corresponding to the plurality of first electrodes; a polymer layer filled between the substrate and the second chip; and a fused solder layer disposed in the polymer layer and electrically connecting between the first and second electrodes.

In some embodiments, the fused solder layer may include at least one of tin (Sn) and indium (In).

In other embodiments, the polymer layer may include at least one selected from a group consisting of diglycidyl ether of bisphenol A, tetraglycidyl 4,4′-diaminodiphenylmethane, tri diaminodiphenylmethane, isocyanate and bismaleimide.

In still other embodiments, the semiconductor device may further include solder particles floating in the polymer layer.

In even other embodiments, the solder particles may include a material identical to that of the fused solder layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view for explaining a semiconductor device according to an embodiment of the present invention;

FIGS. 2A, 3A, and 5A are cross-sectional views for explaining a method of manufacturing a semiconductor device according to an embodiment of the present invention;

FIGS. 2B, 3B, and 5B are partial enlarged views of FIGS. 2A, 3A, and 5A;

FIGS. 4A and 4B are cross-sectional views for explaining laser beam irradiation according to embodiments of the present invention; and

FIGS. 6 to 8 are cross-sectional views for explaining a method of manufacturing a semiconductor device according to another embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the description herein, it will also be understood that when an element is referred to as being “on” another element, it can be directly on the other element, or a third element may be intervened between them. In addition, in the drawings, the thicknesses of elements are exaggerated for effective explanation of technical content.

Example embodiments are described herein with reference to cross-sectional or plan views that are ideal example embodiments. In the drawings, the thicknesses of layers and regions are exaggerated for effective explanation of technical content. As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Thus, the regions illustrated in the figures are schematic in nature and their shapes may be not intended to illustrate the actual shape of a region of a device and are not intended to limit the scope of example embodiments. Also, though terms like a first and a second are used to describe various members, components, regions, layers, and/or portions in various embodiments of the present invention, the members, components, regions, layers, and/or portions are not limited to these terms. These terms are used only to differentiate one element from another one. Exemplary embodiments set forth herein may include complementary embodiments thereof.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated elements, but do not preclude the presence or addition of one or more other elements.

Hereinafter, exemplary embodiments of the inventive concept will be described in detail with reference to the accompanying drawings.

(Semiconductor Device)

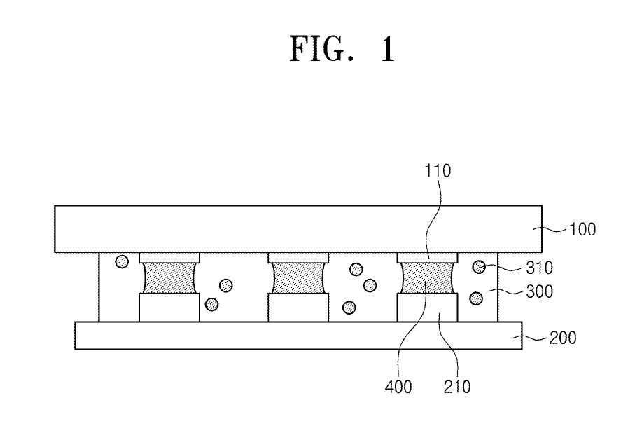

FIG. 1 is a cross-sectional view for explaining a semiconductor device according to an embodiment of the present invention.

Referring to FIG. 1, a semiconductor device may include a substrate 100, a semiconductor chip 200, a polymer layer 300 disposed between the substrate 100 and the semiconductor chip 200, and a fused solder layer 400 disposed in the polymer layer 300 and electrically connecting between the substrate 100 and the semiconductor chip 200.

The substrate 100 may include a transparent glass. According to an aspect, the substrate 100 may be flexible. According to another example, the substrate 100 may be a printed circuit board (PCB) 100.

A plurality of first electrodes 110 may be disposed on one surface of the substrate 100. The plurality of first electrodes 110 may be separated by a predetermined distance from each other.

The semiconductor chip 200 may be disposed separate from and opposite to the substrate 100. A plurality of second electrodes 210 may be disposed on one surface of the semiconductor chip 200. The plurality of second electrodes 210 may be disposed at positions respectively corresponding to the first electrodes 110. The one surface of the substrate 100 and the one surface of the semiconductor chip 200 may face each other in order for the first and second electrodes 110 and 210 to face each other. According to another example, a flexible substrate 100 or a glass substrate 100 may be used instead of the semiconductor chip 200.

The polymer layer 300 does not react at certain temperature or lower, and may maintain a certain viscosity and changes according to temperature. According to an embodiment of the present invention, the polymer layer 300 may include an oxidizing agent. The oxidizing agent may perform a function of removing a natural oxide film on the surface of the first and second electrodes 110 and 210. The polymer layer 300 may include at least one selected from a group consisting of diglycidyl ether of bisphenol A, tetraglycidyl 4,4′-diaminodiphenylmethane, tri diaminodiphenylmethane, isocyanate and bismaleimide.

In addition, the polymer layer 300 may further include additives. The additives may include a curing agent, and the curing agent may perform a function of reacting with the polymer in the polymer layer 300 and curing the polymer. The curing agent may use amine family and anhydride. Here, as an unlimited example of the amine curing agent, there are m-phenylenediamine (MPDA), diaminodiphenylmethane (DDM), and diaminodiphenylsulphone (DDS). As an unlimited example of the anhydride, there are methyl nadic anhydride (MNA), dodecenyl succinic anhydride (DDSA), maleic anhydride (MA), succinic anhydride (SA), methyltetrahydrophthalic anhydride (MTHPA), a hexahydrophthalic anhydride (HHPA), tetrahydrophthalic anhydride (THPA), and pyromellitic dianhydride (PMDA).

The fused solder layer 400 may be disposed between the first and second electrodes 110 and 210 and electrically connect one of the first electrodes 110 and the second electrode 210 corresponding to the selected first electrode 110. The fused solder layer 400 may include at least one of tin (Sn) and indium (In).

According to an embodiment of the present invention, the semiconductor device may further include solder particles 310 floating in the polymer layer 300. The solder particles 310 are not electrically connected to the first and second electrodes 110 and 210. The solder particles 310 may include a material substantially identical to that of the fused solder layer 400. For example, the solder particles 310 may include at least one of tin (Sn) and indium (In).

### First Embodiment of a Method of Manufacturing a Semiconductor Device

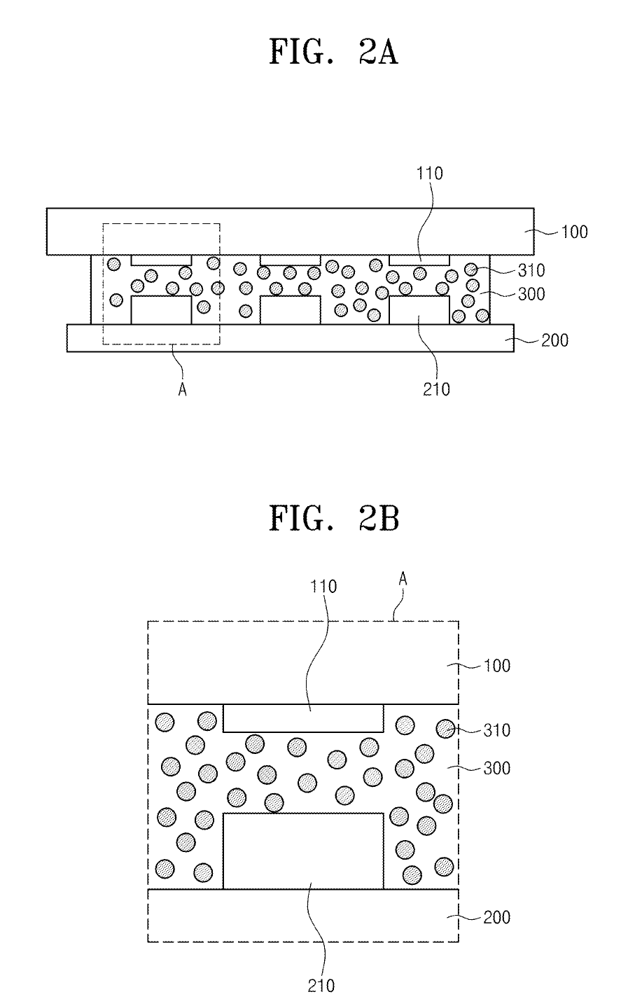

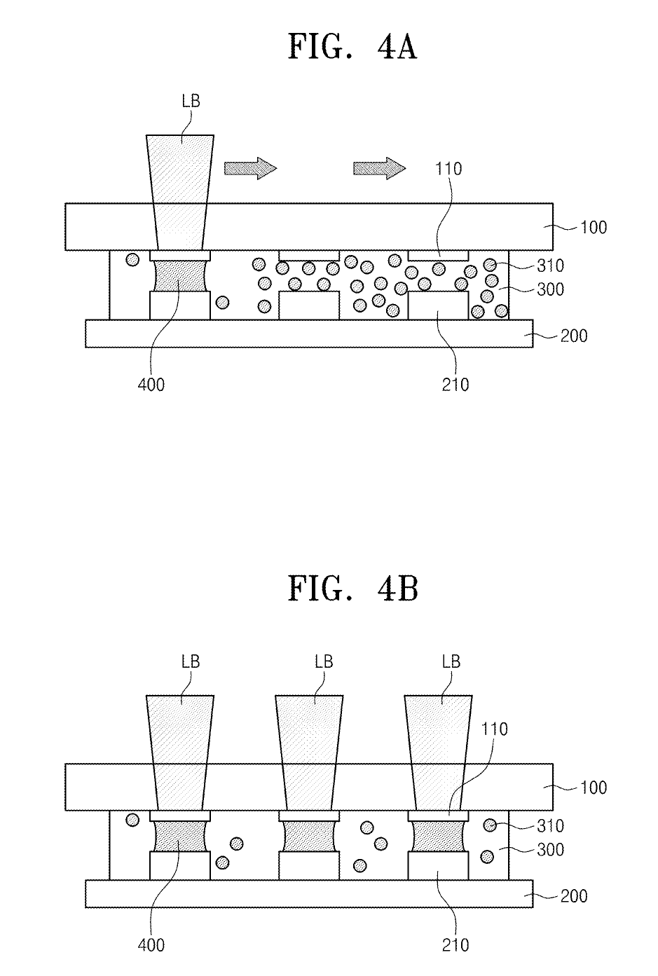

FIGS. 2A, 3A, and 5A are cross-sectional views for explaining a method of manufacturing a semiconductor device according to an embodiment of the present invention. FIGS. 2B, 3B, and 5B are partial enlarged views of FIGS. 2A, 3A, and 5A. FIGS. 4A and 4B are cross-sectional views for explaining laser beam irradiation according to embodiments of the present invention.

Referring to FIGS. 2A and 2B, the polymer layer 300 including the solder particles 310 may be filled in between the substrate 100 on which the plurality of first electrodes 110 are formed and the semiconductor chip 200 on which the plurality of second electrodes 210 are formed.

The substrate 100 may include a transparent glass. In addition, the solder particles 310 in the polymer layer 300 may be randomly dispersed. As described above, the polymer layer 300 may include the oxidizing agent and the curing agent.

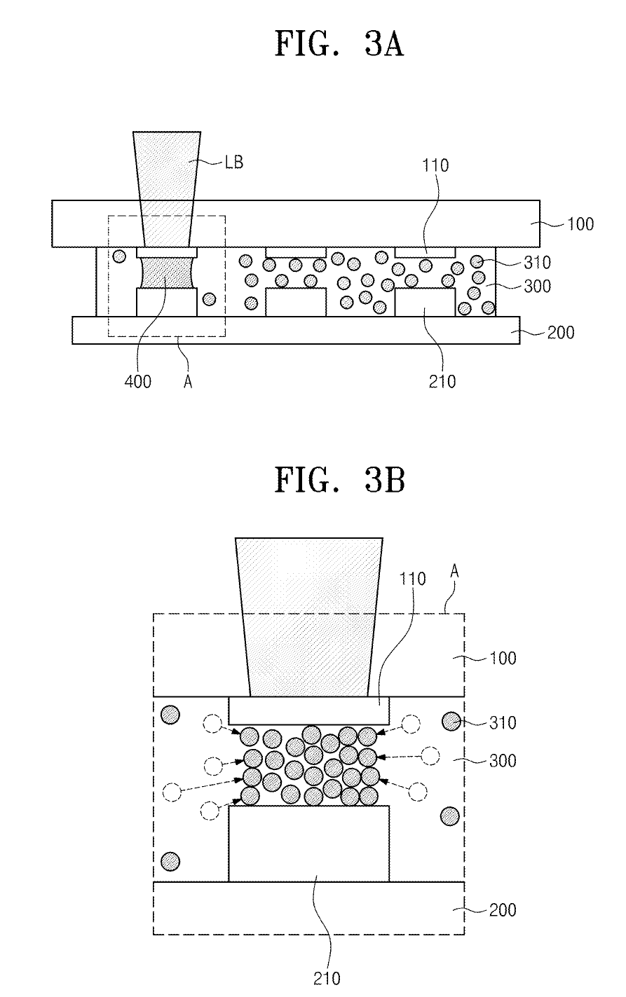

Referring to FIGS. 3A and 3B, the first electrode 110 may be locally irradiated with a laser beam LB. The laser beam LB may be transmitted through the transparent substrate 100 and transfer heat to the first electrode 110, and be transferred to the second electrode 210 facing the first electrode 110. The heat may be transferred to polymer layer 300 between the first and second electrodes 110 and 210, and the solder particles 310. The oxidizing agent in the polymer layer 300 may be activated by the heat and remove the natural oxide film of the surface of the first and second electrodes 110 and 210. The solder particles 310 adjacent to the first and second electrodes 110 and 210 from which the oxide film is removed may be condensed around the first and second electrodes 110 and 210, and wetted and bonded to the first and second electrodes 110 and 210. Accordingly, the fused solder layer 400 electrically connecting between the first and second electrodes 110 and 210 may be formed.

According to an embodiment of FIG. 4A, the laser beam LB may be sequentially irradiated on each of the plurality of first electrodes 110. According to another embodiment of FIG. 4B, a plurality of the laser beams LB may be irradiated on the plurality of first electrodes 110 at a time.

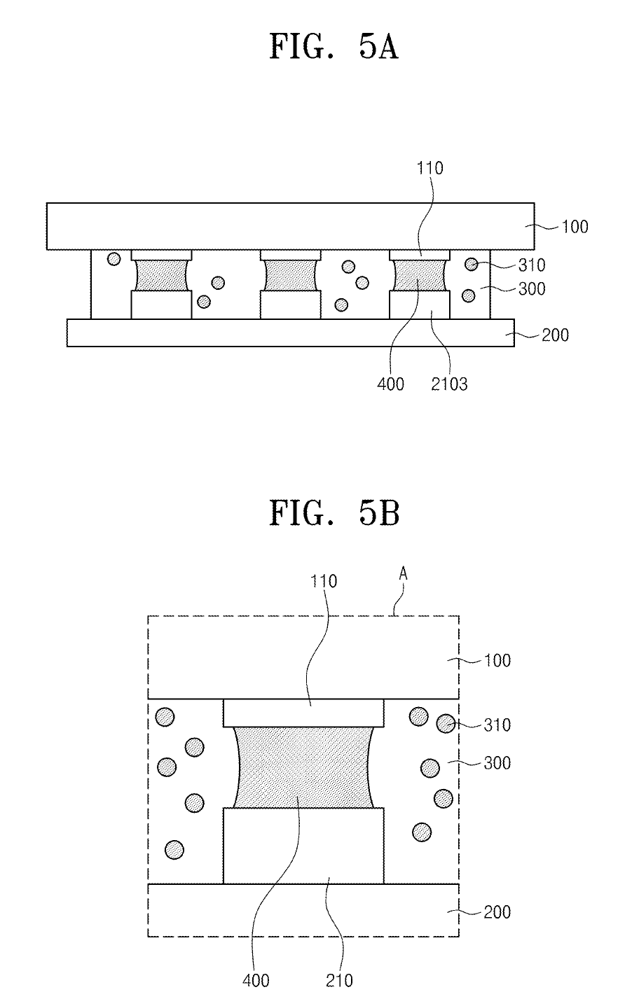

Referring FIGS. 5A and 5B, when the irradiation by the laser beam LB is stopped, the temperature may be gradually lowered, the fused solder layer 400 may be solidified, and compounds between metals between the first and second electrodes 110 and 210 and the fused solder layer 400 may be strongly bonded.

According to an aspect of the present invention, the polymer layer 300 may be cured by using the curing agent in the polymer layer 300. Accordingly, further strong bond may be formed between the substrate 100 and the semiconductor chip 200.

In such a way, the solder particles 310 may be condensed on the first and second electrodes 110 and 210 by removing the oxide film between the first and second electrodes 110 and 210 by using the oxidizing agent in the polymer layer 300. In addition, only the condensed solder particles 310 are fused by the heat of the laser beam LB and wetted and bonded on the surface of the first and second electrodes 110 and 210. Accordingly, the solder particles 310 not fused between the adjacent fused solder layers may be separated by a distance enough not to be short-circuited from the first electrode 110, the second electrode 210, or the fused solder layer. In addition, while the first and second electrodes 110 and 210 are bonded with the fused solder layer 400, the external pressure is not applied and substrate deformation can be prevented.

### Second Embodiment of the Method of Manufacturing the Semiconductor Device

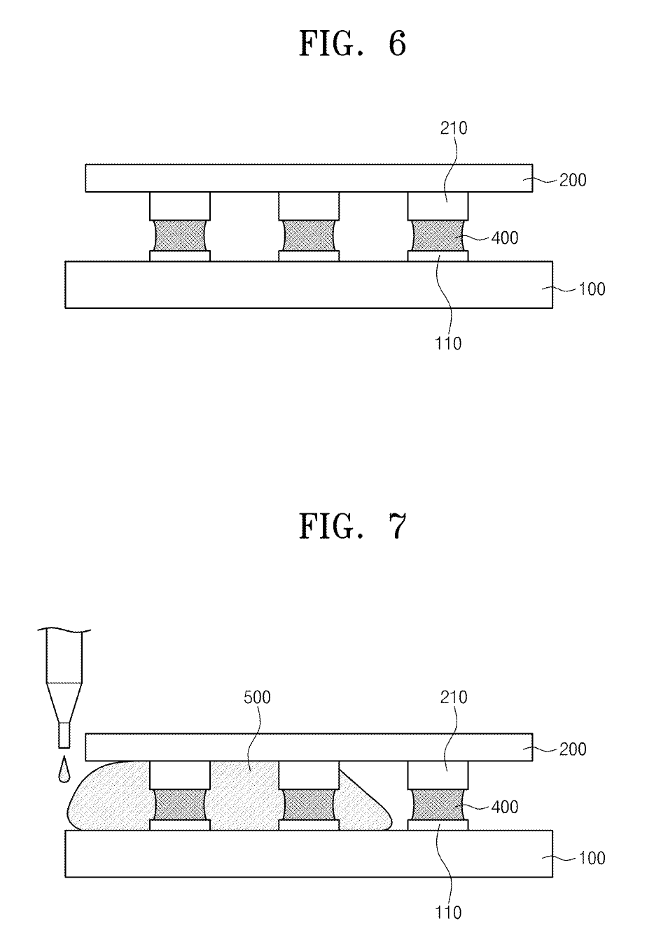

FIGS. 6 to 8 are cross-sectional views for explaining a method of manufacturing a semiconductor device according to another embodiment of the present invention.

Referring to FIG. 6, the first electrodes 110 of the substrate 100 and the second electrodes 210 of the semiconductor chip 200 may be electrically connected through the fused solder layer 400. Description about this is substantially identical to those in relation to FIGS. 2A to 5A and FIGS. 2B to 5B and is omitted.

The polymer layer 300 between the first and second electrodes 110 and 210 may be removed. In order to easily remove the polymer layer 300, the curing agent may not be added.

While the polymer layer 300 is removed, the solder particles 310 not fused may be removed together. For example, the polymer layer 300 and the solder particles 310 may be removed by using a solvent spray.

Referring to FIG. 7, an underfill 500 may be filled between the substrate 100 and the semiconductor chip 200.

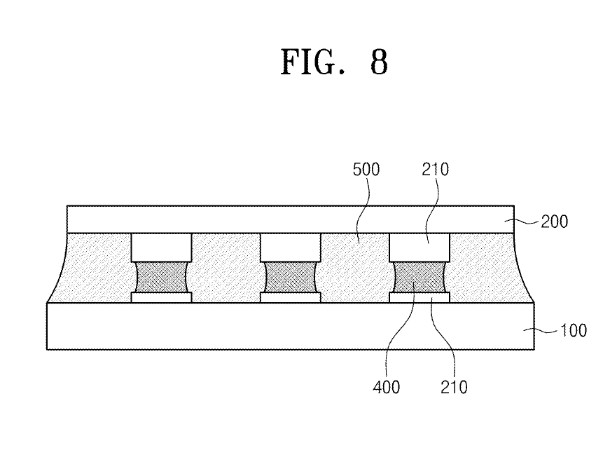

Referring to FIG. 8, the underfill 500 may be cured at lower temperature than a melting point of the fused solder ball.

Accordingly, a difference in coefficient of thermal expansion (CTE) between the semiconductor chip 200 and the substrate 100 may be reduced by the underfill 500, and bonding tolerating an external stress, heat, or moisture absorption may be formed.

According to embodiments of the present invention, solder particles can be condensed on first and second electrodes by removing an oxide film between first and second electrodes with an oxidizing agent in a polymer layer. In addition, only the condensed solder particles can be fused by heat of a laser beam, and wetted and bonded on the surfaces of the first and second electrodes. Accordingly, solder particles not fused between adjacent fused solder layers can be separated by a distance enough not to be short-circuited from the first and second electrodes or the fused solder layer. In addition, while the first and second electrodes are bonded with the fused solder layer, the external pressure is not applied and substrate deformation can be prevented.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing a semiconductor device, comprising:
preparing a substrate transparent and having a plurality of first electrodes thereon;
disposing a semiconductor chip having a plurality of second electrodes thereon on the substrate to allow the first and second electrodes to respectively face each other;
forming a polymer layer comprising solder particles and an oxidizing agent between the substrate and the semiconductor chip; and
locally fusing the solder particles between the first and second electrodes by using a laser beam and forming a fused solder layer electrically connecting between the first and second electrodes.

2. The method of claim 1, wherein the locally fusing of the solder particles comprises:
locally irradiating the substrate having the first electrode formed thereon with a laser beam;
transferring local heat to around the first and second electrodes by using the laser beam;
activating the oxidizing agent in a polymer by the heat transferred to around the first and second electrodes and removing oxide films on surfaces of the first and second electrodes; and
fusing solder particles adjacent to the first and second electrodes from which the oxide films are removed, and wetting and bonding to the first and second electrodes.

3. The method of claim 2, wherein the laser beams is sequentially irradiated on each of the plurality of first electrodes.

4. The method of claim 2, wherein a plurality of laser beams are irradiated on the plurality of first electrodes at a time.

5. The method of claim 1, further comprising, after the forming of the fused solder layer, removing a remained polymer layer; and
filling an underfill between the substrate and the semiconductor chip.

6. The method of claim 1, wherein, while the solder particles between the first and second electrodes are locally fused by using a laser beam and the fused solder layer which electrically connects the first and second electrodes is formed, external pressure is not applied.

7. The method of claim 1, further comprising curing the polymer layer by using a curing agent after the forming of the fused solder layer, wherein the polymer layer further comprises the curing agent.

8. A semiconductor device comprising:
a substrate having a plurality of first electrodes;
a semiconductor chip having a plurality of second electrodes corresponding to the plurality of first electrodes;
a polymer layer filled between the substrate and the second chip; and
a fused solder layer disposed in the polymer layer and electrically connecting between the first and second electrodes.

9. The semiconductor device of claim 8, wherein the fused solder layer comprises at least one of tin (Sn) and indium (In).

10. The semiconductor device of claim 8, wherein the polymer layer comprises at least one selected from a group consisting of diglycidyl ether of bisphenol A, tetraglycidyl 4,4′-diaminodiphenylmethane, tri diaminodiphenylmethane, isocyanate and bismaleimide.

11. The semiconductor device of claim 8, further comprising solder particles floating in the polymer layer.

12. The semiconductor device of claim 11, wherein the solder particles comprise a material identical to that of the fused solder layer.
